(19) United States
(12) Patent Application Publication
(10) Pub. No.: US 2021/0365659 A1
(43) Pub. Date: Nov. 25, 2021

(54) INTEGRATED PHOTO-SENSING DETECTION DISPLAY APPARATUS AND METHOD OF FABRICATING INTEGRATED PHOTO-SENSING DETECTION DISPLAY APPARATUS

(71) Applicant: BOE Technology Group Co., Ltd., Beijing (CN)

(72) Inventors: Shengji Yang, Beijing (CN); Xue Dong, Beijing (CN); Xiaochuan Chen, Beijing (CN); Hui Wang, Beijing (CN); Pengcheng Lu, Beijing (CN)

(73) Assignee: BOE Technology Group Co., Ltd., Beijing (CN)

(21) Appl. No.: 16/626,791

(22) PCT Filed: Dec. 3, 2018
(86) PCT No.: PCT/CN2018/118911

§ 371 Date: Dec. 26, 2019

(51) Int. Cl. G06K 9/00; G06K 9/20; G02B 27/30; G02B 27/42; G02B 5/18; H01L 27/146

(52) U.S. Cl. CPC G06K 9/0004; G06K 9/2036; G06K 9/209; G06K 9/2027; G02B 27/30; G02B 2207/101; G02B 5/1866; H01L 27/14678; H01L 27/14623; H01L 27/14685; G02B 27/4205

(57) ABSTRACT

An integrated photo-sensing detection display substrate having a subpixel region and an inter-subpixel region. The integrated photo-sensing detection display substrate includes a base substrate; a plurality of light emitting elements on the base substrate and configured to emit light, a portion of the light being totally reflected by a surface thereby forming totally reflected light; a light shielding layer between the plurality of light, emitting elements and the base substrate configured to block at least a portion of diffusedly reflected light from passing through, the light shielding layer having a light path aperture in the inter-subpixel region allowing at least a portion of the totally reflected light to pass through thereby forming a signal-enriched light beam; a diffraction grating layer configured to at least partially collimate the signal-enriched light beam thereby forming a collimated light beam; and a photosensor configured to detect the collimated light beam.

### TECHNICAL FIELD

The present invention relates to photo-sensing detection technology, more particularly, to an integrated photo-sensing detection display apparatus and a method of fabricating an integrated photo-sensing detection display apparatus.

### BACKGROUND

In recent years, various methods have been proposed in fingerprint and palm print recognition. Examples of optical method for recognizing fingerprint and palm print include total reflection method, light-path separation method, and scanning method. In a total reflection method, light from a light source such as ambient light enters into a pixel, and is totally reflected on the surface of a package substrate. When a finger or palm touches the display panel, the total reflection condition of the surface changes locally upon touch, leading to a disruption of the total reflection locally. The disruption of the total reflection results in a reduced reflection. Based on this principle, the ridge lines of a finger may be differentiated from the valley lines. Alternatively, fingerprint and palm print may be recognized by detecting changes in capacitance when a finger or palm touches the display panel.

### SUMMARY

In one aspect, the present invention provides an integrated photo-sensing detection display substrate having a subpixel region and an inter-subpixel region, comprising a base substrate; a plurality of light emitting elements on the base substrate and configured to emit light, a portion of the light being totally reflected by a surface thereby forming totally reflected light; a light shielding layer between the plurality of light emitting elements and the base substrate and configured to block at least a portion of diffusedly reflected light from passing through, the light shielding layer having a light path aperture in the inter-subpixel region allowing at least a portion of the totally reflected light to pass through thereby forming a signal-enriched light beam; a diffraction grating layer on a side of the base substrate away from the light path aperture and configured to at least partially collimate the signal-enriched light beam thereby forming a collimated light beam; and a photosensor on a side of the diffraction grating layer away from the base substrate and configured to detect the collimated light beam, thereby detecting fingerprint information.

Optionally, the light shielding layer has an area greater than an area of the subpixel region; and an orthographic projection of the light shielding layer on the base substrate covers an orthographic projection of the subpixel region on the base substrate.

Optionally, the photosensor has an area smaller than an area of the integrated photo-sensing detection display substrate; and the diffraction grating layer is configured to form collimated light beams transmitting toward the photosensor respectively at different exit angles depending on a light exiting position on the diffraction grating layer relative to the photosensor.

Optionally, the diffraction grating layer comprises a first diffraction region and a second diffraction region; the first diffraction region is configured to collimate a first signal-enriched light beam transmitted to the first diffraction region to exit the first diffraction region at a first exit angle, thereby forming a first collimated light beam toward the photosensor; and the second diffraction region is configured to collimate a second signal-enriched light beam transmitted to the second diffraction region to exit the second diffraction region at a second exit angle, thereby forming a second collimated light beam toward the photosensor.

Optionally, the first diffraction region has a first grating pitch; the second diffraction region has a second grating pitch; and the first grating pitch and the second grating pitch are different from each other.

Optionally, the second diffraction region surrounds the first diffraction region; and the first grating pitch is greater than the second grating pitch.

Optionally, an orthographic projection of the second diffraction region on the base substrate is on a side of an orthographic projection of the first diffraction region on the base substrate away from an orthographic projection of the photosensor on the base substrate.

Optionally, the integrated photo-sensing detection display substrate further comprises a plurality of thin film transistors configured to drive light emission of the plurality of light emitting elements; a respective one of the plurality of thin film transistors comprises a drain electrode; the light shield layer comprises a plurality of light shielding blocks spaced apart from each other; and a respective one of the plurality of light shielding blocks is electrically connected to the drain electrode of a respective one of the plurality of thin film transistors.

Optionally, the integrated photo-sensing detection display substrate further comprises a first insulating layer between the drain electrode and the light shield layer.

Optionally, the respective one of the plurality of light emitting elements comprises a first electrode electrically connected to the light shielding layer.

Optionally, the integrated photo-sensing detection display substrate further comprises a second insulating layer between the first electrode and the light shield layer.

Optionally, the second insulating layer extends into the light path aperture.

Optionally, the first electrode is made of a substantially transparent conductive material.

Optionally, the integrated photo-sensing detection display substrate further comprises a pixel definition layer defining a plurality of subpixel apertures; and the pixel definition layer has an inter-subpixel aperture in the inter-subpixel region, allowing at least a portion of the totally reflected light to pass through sequentially the inter-subpixel aperture and the light path aperture.

Optionally, the inter-subpixel aperture is larger than the light path aperture; and an orthographic projection of the light shielding layer on the base substrate covers an orthographic projection of the pixel definition layer on the base substrate.

Optionally, the diffraction grating layer is a nano-diffraction grating layer.

Optionally, an orthographic projection of the light shield layer on the base substrate is substantially non-overlapping with an orthographic projection of a plurality of data lines and a plurality of gate lines on the base substrate.

In another aspect, the present invention provides an integrated photo-sensing detection display panel, comprising the integrated photo-sensing detection display substrate described herein or fabricated by a method described herein; and a counter substrate facing the integrated photo-sensing detection display substrate; wherein the plurality of light emitting elements are configured to emit light toward the counter substrate, a portion of the light being totally reflected by a surface of the counter substrate facing away the integrated photo-sensing detection display substrate thereby forming the totally reflected light; and the photosensor is configured to detect fingerprint information generated from a touch at any portion of the counter substrate.

In another aspect, the present invention provides an integrated photo-sensing detection display apparatus, comprising the integrated photo-sensing detection display panel described herein or fabricated by a method described herein, and one or more integrated circuits connected to the integrated photo-sensing detection display panel.

In another aspect, the present invention provides a method of fabricating an integrated photo-sensing detection display substrate having a subpixel region and an inter-subpixel region, comprising forming a plurality of light emitting elements on a base substrate, the plurality of light emitting elements formed to emit light, a portion of the light being totally reflected by a surface thereby forming totally reflected light; forming a light shielding layer between the plurality of light emitting elements and the base substrate, the light shielding layer formed to block at least a portion of diffusedly reflected light from passing through, the light shielding layer formed to have a light path aperture in the inter-subpixel region allowing at least a portion of the totally reflected light to pass through thereby forming a signal-enriched light beam; forming a diffraction grating layer on a side of the base substrate away from the light path aperture, the diffraction grating layer formed to at least partially collimate the signal-enriched light beam thereby forming a collimated light beam; and forming a photosensor on a side of the diffraction grating layer away from the base substrate, the photosensor formed to detect the collimated light beam, thereby detecting fingerprint information.

### BRIEF DESCRIPTION OF THE FIGURES

The following drawings are merely examples for illustrative purposes according to various disclosed embodiments and are not intended to limit the scope of the present invention.

FIG. 1 is a schematic diagram illustrating the structure of an integrated photo-sensing detection display apparatus in some embodiments according to the present disclosure.

FIGS. 2A to 2C illustrate the structure of a light shield layer in some embodiments according to the present disclosure.

FIG. 3 illustrates the structure of a diffraction grating layer in some embodiments according to the present disclosure.

FIG. 4 is a schematic diagram illustrating the structure of an integrated photo-sensing detection display apparatus in some embodiments according to the present disclosure.

FIGS. 5A to 5C illustrate the structure of a pixel definition layer in some embodiments according to the present disclosure.

FIG. 6 is a schematic diagram illustrating the structure of an integrated photo-sensing detection display apparatus in, some embodiments according to the present disclosure.

FIG. 7 is a schematic diagram illustrating the structure of a diffraction grating layer in some embodiments according to the present disclosure.

FIG. 8 illustrates a method of collimating light from different diffraction regions of a diffraction grating layer to a photosensor in some embodiments according to the present disclosure.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

The present disclosure provides, inter alia, an integrated photo-sensing detection display apparatus and a method of fabricating an integrated photo-sensing detection display apparatus that substantially obviate one or more of the problems due to limitations and disadvantages of the related art. In one aspect, the present disclosure provides an integrated photo-sensing detection display apparatus having a subpixel region and an inter-subpixel region. In some embodiments, the integrated photo-sensing detection display apparatus includes a counter substrate; and an array substrate facing the counter substrate. In some embodiments, the array substrate includes a base substrate; a plurality of light emitting elements on the base substrate and configured to emit light toward the counter substrate, a portion of the light being totally reflected by a surface of the counter substrate facing away the array substrate thereby forming totally reflected light; and a light shielding layer between the plurality of light emitting elements and the base substrate and configured to block at least a portion of diffusedly reflected light from passing through, the light shielding layer having a light path aperture in the inter-subpixel region allowing at least a portion of the totally reflected light to pass through thereby forming a signal-enriched light beam. Optionally, the integrated photo-sensing detection display apparatus further includes a diffraction grating layer on a side of the base substrate away from the light path aperture and configured to at least partially collimate the signal-enriched light beam thereby forming a collimated light beam; and a photosensor on a side of the diffraction grating layer away from the light path aperture and configured to detect the collimated light beam, thereby detecting fingerprint information.

As used herein, a subpixel region refers to a light emission region of a subpixel, such as a region corresponding to a pixel electrode in a liquid crystal display, a region corresponding to a light emissive layer in an organic light emitting diode display panel, or a region corresponding to the light transmission layer in the present disclosure. Optionally, a pixel may include a number of separate light emission regions corresponding to a number of subpixels in the pixel. Optionally, the subpixel region is a light emission region of a red color subpixel. Optionally, the subpixel region is a light emission region of a green color subpixel. Optionally, the subpixel region is a light emission region of a blue color subpixel. Optionally, the subpixel region is a light emission region of a white color subpixel. As used herein, an inter-subpixel region refers to a region between adjacent subpixel regions, such as a region corresponding to a black matrix in a liquid crystal display, a region corresponding a pixel definition layer in an organic light emitting diode display panel, or a black matrix in the present display panel. Optionally, the inter-subpixel region is a region between adjacent subpixel regions in a same pixel. Optionally, the inter-subpixel region is a region between two adjacent subpixel regions from two adjacent pixels. Optionally, the inter-subpixel region is a region between a subpixel region of a red color subpixel and a subpixel region of an adjacent green color subpixel. Optionally, the inter-subpixel region is a region between a subpixel region of a red color subpixel and a subpixel region of an adjacent blue color subpixel. Optionally, the inter-subpixel region is a region between a subpixel region of a green color subpixel and a subpixel region of an adjacent blue color subpixel.

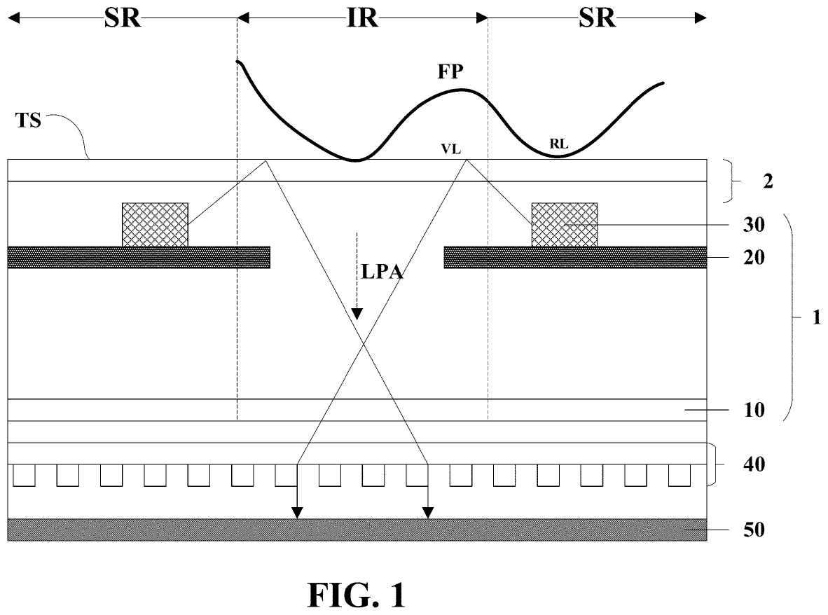

FIG. 1 is a schematic diagram illustrating the structure of an integrated photo-sensing detection display apparatus in, some embodiments according to the present disclosure. Referring to FIG. 1, the integrated photo-sensing detection display apparatus in some embodiments has a subpixel region SR and an inter-subpixel region IR. The integrated photo-sensing detection display apparatus in some embodiments includes an array substrate 1 and a counter substrate 2 facing the array substrate 1. In some embodiments, the array substrate 1 includes a base substrate 10, and a plurality of light emitting elements 30 on the base substrate 10. Various appropriate light emitting elements may be used in the present display substrate. Examples of appropriate light emitting elements include an organic light emitting diode, a quantum dots light emitting diode, and a micro light emitting diode.

The plurality of light emitting elements 30 are configured to emit light toward the counter substrate 2, e.g., for image display. As shown in FIG. 1, at least a portion of the light emitted from the plurality of light emitting elements 30 is reflected by, e.g., totally reflected by a surface TS of the counter substrate 2 facing away the array substrate 1 thereby forming totally reflected light. The surface TS is, for example, a touch surface on which a fingerprint touch occurs. When a finger (or palm) is placed on the side of the counter substrate 2 facing away the array substrate 1, a finger print FP (or a palm print) can be detected. As shown in FIG. 1, the finger print FP has a plurality of ridges lines RL and a plurality of valley lines VL. Light emitted from the plurality of light emitting elements 30 irradiates the plurality of valley lines VL and the plurality of ridge lines RL of the finger print FP (or the palm print). Due to the difference between the plurality of valley lines VL and the plurality of ridge lines RL in the reflection angle and the intensity of reflected light, the light projected onto a photosensor can produce different electrical currents, so that the plurality of valley lines VL and the plurality of ridge lines RL of the finger print FP (or the palm print) can be recognised.

In one example, light irradiates on one of the plurality of valley lines VL. The finger (or the palm) is not in touch with the screen surface (the side of the counter substrate 2 facing away the array substrate 1) in regions corresponding to the plurality of valley lines VL, total reflection conditions in these regions remain intact (for example, the medium on a side of the counter substrate 2 away from the array substrate 1 is air). Light irradiates on the surface TS of the counter substrate 2 facing away the array substrate 1 in the regions corresponding to the plurality of valley lines VL, and (at least a portion of) light is totally reflected by the surface TS of the counter substrate 2 facing away the array substrate 1. The light totally reflected by the surface TS of the counter substrate 2 facing away the array substrate 1 in the regions corresponding to the plurality of valley lines VL is detected.

In another example, light irradiates on one of the plurality of ridge lines RL. The finger (or the palm) is in touch with the screen surface (the side of the counter substrate 2 facing away the array substrate 1) in regions corresponding to the plurality of ridge lines RL, total reflection conditions in these regions are disrupted (for example, the medium on a side of the counter substrate 2 facing away the array substrate 1 is not air but finger). Light irradiates on the surface TS of the counter substrate 2 facing away the array substrate 1 in the regions corresponding to the plurality of ridge lines RL, diffused reflection occurs on the interface, thereby generating diffused reflected light transmitting along various directions. A photosensors proximal to the one of the plurality of ridge lines RL detects less reflected light as compared to the one corresponding to the one of the plurality of valley lines VL. Accordingly, the plurality of ridge lines RL and plurality of valley lines VL can be differentiated and recognized.

Referring to FIG. 1, the array substrate 1 in some embodiments further includes a light shielding layer 20 between the plurality of light emitting elements 30 and the base substrate 10. The light shielding layer 20 is configured to block at least a portion of diffusedly reflected light from passing through. As shown in FIG. 1, the light shielding layer 20 has a light path aperture LPA in the inter-subpixel region IR that allows at least a portion of the totally reflected light to pass through thereby forming a signal-enriched light beam. By having the light path aperture LPA in the inter-subpixel region IR, the diffusedly reflected light can be blocked while allowing the at least a portion of the totally reflected light to pass through, thereby enhancing the signal-noise ratio in detection of the fingerprint information. The diffusedly reflected light can be, for example, the light diffusedly reflected by components of the display apparatus, e.g., lateral walls of one or more layers or metal lines in the display apparatus.

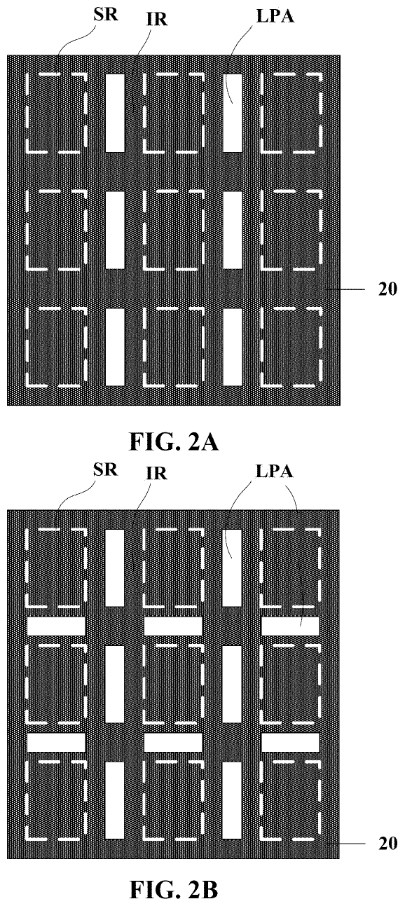

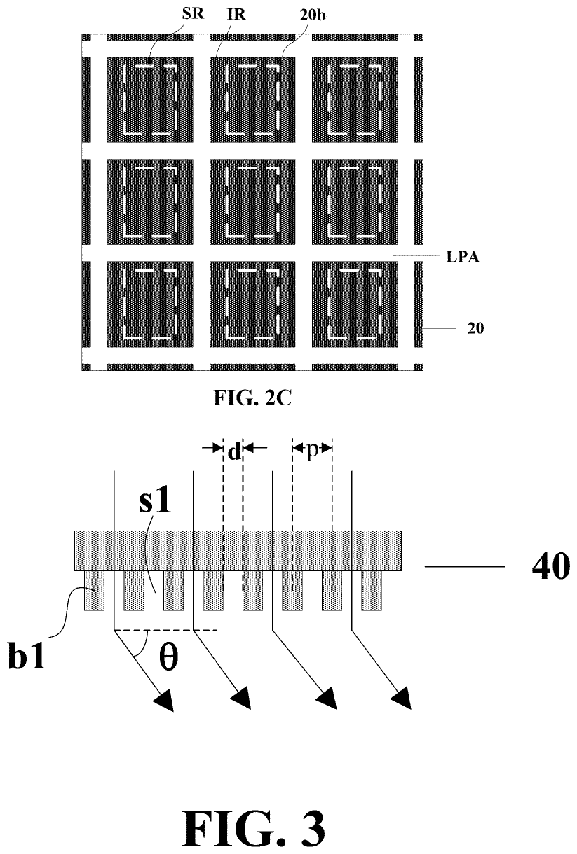

FIGS. 2A to 2C illustrate the structure of a light shield layer in some embodiments according to the present disclosure. Referring to FIG. 2A, the integrated photo-sensing detection display apparatus includes multiple ones of the light path aperture LPA corresponding to multiple subpixels, the multiple ones of the light path aperture LPA are spaced apart from each other. In some embodiments, the light path aperture LPA is between longitudinal sides of adjacent ones of the subpixel region SR. Referring to FIG. 2B, the light path aperture LPA is between longitudinal sides of adjacent ones of the subpixel region SR, as well as between lateral sides of adjacent ones of the subpixel region SR. The multiple ones of the light path aperture LPA are spaced apart from each other, and form a plurality of rows and a plurality of columns. Referring to FIG. 2C, the light path aperture LPA in some embodiments is a continuous network extending throughout an entirety of the integrated photo-sensing detection display apparatus, dividing the light shielding layer 20 into a plurality of light shielding blocks 20b.

Any appropriate light shielding materials and any appropriate fabricating methods may be used to make the light shielding layer 20. For example, a light shielding material may be deposited on the base substrate (e.g., by sputtering or vapor deposition); and patterned (e.g., by lithography such as a wet etching process) to form the light shielding layer 20. Examples of appropriate light shielding materials include, but are not limited to, molybdenum, aluminum, copper, chromium, tungsten, titanium, tantalum, and alloys or laminates containing the same. In one example, the light shielding layer 20 is made of an insulating material, e.g., an insulating black material. In another example, the light shielding layer 20 is made of a conductive material, e.g., a reflective metallic material.

In some embodiments, the light shielding layer 20 has an area greater than an area of the subpixel region SR, as shown in FIGS. 2A to 2C. An orthographic projection of the light shielding layer 20 on the base substrate 10 covers an orthographic projection of the subpixel region SR on the base substrate 10, as shown in FIG. 1. In some embodiments, the light path aperture LPA has an area smaller than an area of the inter-subpixel region IR.

Referring to FIG. 1, the integrated photo-sensing detection display apparatus in some embodiments further includes a diffraction grating layer 40 on a side of the base substrate 10 away from the light path aperture LPA and the light shielding layer 20. The diffraction grating layer 40 is configured to at least partially collimate the signal-enriched light beam thereby forming a substantially collimated light beam.

Various appropriate diffraction grating devices may be used in the present disclosure. For example, the diffraction grating may be of any appropriate type, including a reflective-type diffraction grating and a transmissive-type diffraction grating. In one example, the diffraction grating is a diffraction grating lens. In another example, the diffraction grating is a nano-diffraction grating.

In some embodiments, the diffraction grating layer 40 includes a plurality of barriers spaced apart by a plurality slits, as shown in FIG. 1. FIG. 3 illustrates the structure of a diffraction grating layer in some embodiments according to the present disclosure. Referring to FIG. 3, the diffraction grating layer 40 has a plurality of barriers b1 spaced apart by a plurality slits s1. The diffraction grating layer 40 has a pitch p. A distance between two directly adjacent barriers of the plurality of barriers b1 of the diffraction grating layer 40 is denoted as d, which is substantially a width of a respective one of the plurality of slits s1. Assuming an incident angle of the signal-enriched light beam to the diffraction grating layer 40 is approximately 90 degrees, an exit angle θ of the collimated light beam exiting the diffraction grating layer 40 can be calculated according to Equation (1):

n*d*sin θ=m*λ (1);

wherein n is a refractive index of the diffraction grating layer 40, d is an inter-barrier distance between lateral walls of two directly adjacent barriers of the plurality of barriers b1 of the diffraction grating layer 40; θ stands for an exit angle of the collimated light beam exiting the diffraction grating layer 40; λ is a wavelength of the signal-enriched light beam incident to the diffraction grating layer 40; and m is an order of diffraction (m=0, ±1, ±2, ±3, ±4 . . . ), e.g., m=1.

Based on Equation (1), the exit angle θ of the collimated light beam exiting the diffraction grating layer 40 can be designed depending on an exiting position of the collimated light beam relative to a photosensor for detecting the collimated light beam.

Referring to FIG. 1, the integrated photo-sensing detection display apparatus in some embodiments further includes a photosensor 50 on a side of the diffraction grating layer 40 away from the base substrate 10. The photosensor 50 is configured to detect the collimated light beam exiting the diffraction grating layer 40, thereby detecting fingerprint information. In some embodiments, the photosensor 50 has an area smaller than an area of the integrated photo-sensing detection display apparatus. The diffraction grating layer 40 is configured to form the collimated light beam transmitting toward the photosensor 50 at different exit angles depending on a light exiting position on the diffraction grating layer 40 relative to the photosensor 50. Thus, fingerprint information generated from a touch at any portion of the counter substrate 2 can be detected by the photosensor 50 of a relatively small size as compared to the counter substrate 2.

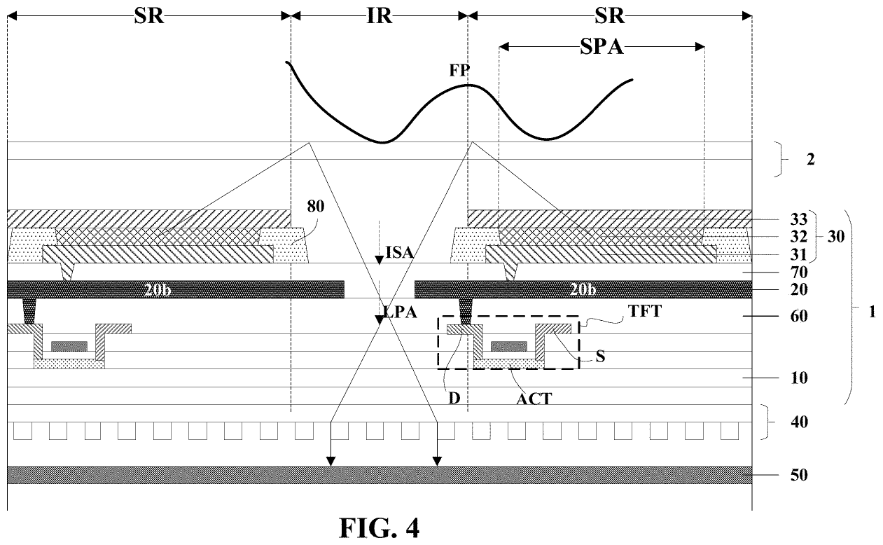

FIG. 4 is a schematic diagram illustrating the structure of an integrated photo-sensing detection display apparatus in some embodiments according to the present disclosure. Referring to FIG. 4, the array substrate 1 of the integrated photo-sensing detection display apparatus in some embodiments further includes a plurality of thin film transistors TFT configured to drive light emission of the plurality of light emitting elements 30. As shown in FIG. 4, a respective one of the plurality of thin film transistors TFT includes a drain electrode D and a source electrode S respectively connected to an active layer ACT, a data signal transmits from the source electrode S to the drain electrode D when a respective one of the plurality of thin film transistors TFT is turned on.

In one example, the light shield layer 20 includes a plurality of light shielding blocks 20b spaced apart from each other (and insulated from each other). In some embodiments, a respective one of the plurality of light shielding blocks 20b is electrically connected to the drain electrode D of a respective one of the plurality of thin film transistors TFT, as shown in FIG. 4. Optionally, the respective one of the plurality of light shielding blocks 20b is at least partially in the subpixel region SR. Optionally, an orthographic projection of a respective one of the plurality of light shielding blocks 20b on the base substrate 10 covers an orthographic projection of the subpixel region SR in a respective one of the plurality of subpixels of the integrated photo-sensing detection display apparatus on the base substrate 10. Optionally, the respective one of the plurality of light shielding blocks 20b is at least partially in the inter-subpixel region IR. Optionally, the respective one of the plurality of light shielding blocks 20b extends from the subpixel region SR into the inter-subpixel region IR. Optionally, the respective one of the plurality of light shielding blocks 20b occupies a peripheral region of the subpixel region SR in a respective one of the plurality of subpixels of the integrated photo-sensing detection display apparatus, but is absent in a center region of the subpixel region SR in a respective one of the plurality of subpixels of the integrated photo-sensing detection display apparatus.

Optionally, the array substrate 1 further includes a first insulating layer 60 between the drain electrode D and the light shield layer 20, e.g., between a respective one of the plurality of light shielding blocks 20b and the drain electrode D of a respective one of the plurality of thin film transistors TFT.

In some embodiments, a respective one of the plurality of light emitting elements 30 includes a first electrode 31, a light emitting layer 32, and a second electrode 33 sequentially disposed on the base substrate 10. The first electrode 31 in some embodiments is electrically connected to the light shielding layer 20. e.g., electrically connected to a respective one of the plurality of light shielding blocks 20b. The light emitting layer 32 is on a side of the first electrode 31 away from the base substrate 10, and the second electrode 33 is on a side of the light emitting layer 32 away from the first electrode 31.

Optionally, the array substrate 1 further includes a second insulating layer 70 between the first electrode 31 and the light shield layer 20, e.g., between a respective one of the plurality of light shielding blocks 20b and the first electrode 31 of the respective one of the plurality of light emitting elements 30. Optionally, the second insulating layer 70 is made of an optically transparent material, and the second insulating layer 70 extends into the light path aperture LPA.

Optionally, the first electrode 31 is made of a substantially transparent conductive material. As used herein, the term “substantially transparent” means at least 50 percent (e.g., at least 60 percent, at least 70 percent, at least 80 percent, at least 90 percent, and at least 95 percent) of an incident light in the visible wavelength range transmitted therethrough. Optionally, the second electrode 33 is made of a substantially transparent conductive material.

Optionally, the first electrode 31 is made of a reflective conductive material, e.g., a metallic material. Optionally, the second electrode 33 is made of a substantially transparent conductive material. When the first electrode 31 is made of a reflective conductive material, the light shielding layer 20 (e.g., a respective one of the plurality of light shielding blocks 20b) optionally is absent in a center region of the subpixel region SR of the plurality of subpixels. Optionally, the first electrode 31 is made of a reflective conductive material, and the light shielding layer 20 (e.g., a respective one of the plurality of light shielding blocks 20b) is present in the center region of the subpixel region SR of the plurality of subpixels.

Referring to FIG. 4, the array substrate 1 of the integrated photo-sensing detection display apparatus in some embodiments further includes a pixel definition layer 80 defining a plurality of subpixel apertures SPA. Optionally, an orthographic projection of the light shielding layer 20 on the base substrate 10 covers an orthographic projection of the plurality of subpixel apertures SPA on the base substrate 10. Optionally, an orthographic projection of the light shielding layer 20 on the base substrate 10 covers an orthographic projection of the plurality of light emitting elements 30 on the base substrate 10.

In some embodiments, the pixel definition layer 80 has an inter-subpixel aperture ISA in the inter-subpixel region IR. The inter-subpixel aperture ISA allows at least a portion of the totally reflected light to pass through. In one example, the totally reflected light sequentially passes through the inter-subpixel aperture ISA and the light path aperture IPA before reaching the diffraction grating layer 40. Optionally, the inter-subpixel aperture ISA is larger than the light path aperture LPA, and an orthographic projection of the light shielding layer 20 on the base substrate 10 covers an orthographic projection of the pixel definition layer 80 on the base substrate 10. Optionally, the inter-subpixel aperture ISA has a size substantially the same as the light path aperture LPA. Optionally, the inter-subpixel aperture ISA is smaller than the light path aperture LPA.

To prevent occurrence of parasitic capacitance caused by the light shielding layer 20, in some embodiments, an orthographic projection of the light shield layer 20 on the base substrate 10 is substantially non-overlapping with an orthographic projection of a plurality of data lines and a plurality of gate lines on the base substrate 10. As used herein, the term “substantially non-overlapping” refers to two orthographic projections being at least 80 percent (e.g., at least 85 percent, at least 90 percent, at least 95 percent, at least 99 percent, and 100 percent) non-overlapping. Moreover, the insulating layer (e.g., the first insulating layer 60) can have a relatively large thickness to further reduce the parasitic capacitance between the light shielding layer 20 and signal lines in the array substrate 1.

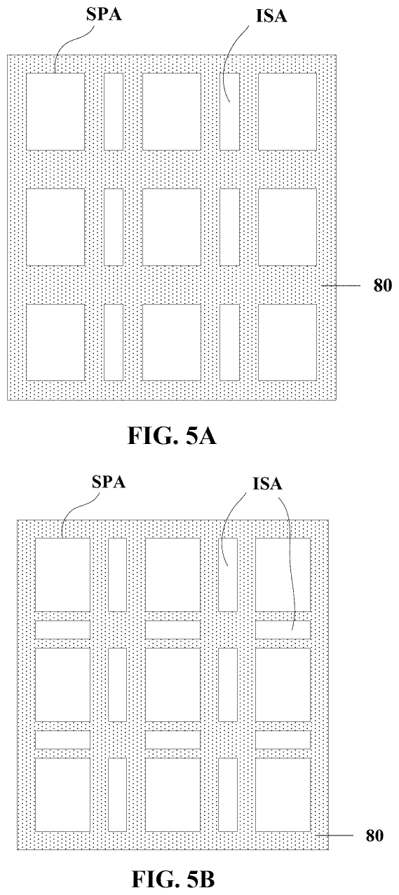

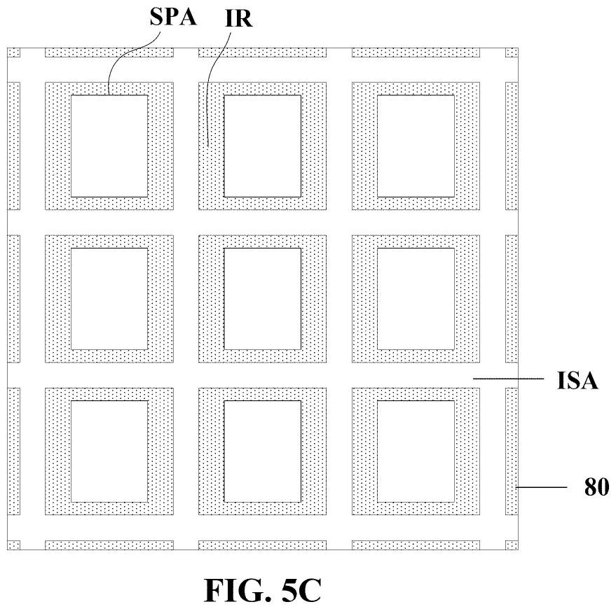

FIGS. 5A to 5C illustrate the structure of a pixel definition layer in some embodiments according to the present disclosure. Referring to FIG. 5A, the integrated photo sensing detection display apparatus includes multiple ones of the inter-subpixel aperture ISA corresponding to multiple subpixels, the multiple ones of the inter-subpixel aperture ISA are spaced apart from each other. In some embodiments, the inter-subpixel aperture ISA is between longitudinal sides of adjacent ones of the plurality of subpixel apertures SPA. Referring to FIG. 5B, the inter-subpixel aperture ISA is between longitudinal sides of adjacent ones of the plurality of subpixel apertures SPA, as well as between lateral sides of adjacent ones of the plurality of subpixel apertures SPA. The multiple ones of the inter-subpixel aperture ISA are spaced apart from each other, and form a plurality of rows and a plurality of columns. Referring to FIG. 5C, the inter-subpixel aperture ISA in some embodiments forms a continuous network extending throughout an entirety of the integrated photo-sensing detection display apparatus.

Any appropriate pixel definition materials and any appropriate fabricating methods may be used to make the pixel definition layer 80. For example, a pixel definition material may be deposited on the base substrate (e.g., by sputtering or vapor deposition); and patterned (e.g., by lithography such as a wet etching process) to form the pixel definition layer 80. Examples of appropriate pixel definition materials include, but are not limited to, silicon oxide (SiO_{y}), silicon nitride (SiN_{y}, e.g., Si₃N₄), silicon oxynitride (SiOₓN_{y}), polyimide, polyimide, acryl resin, benzocyclobutene, and phenol resin. Optionally, the pixel definition layer 80 may have a single-layer structure or a stacked-layer structure including two or more sub-layers (e.g., a stacked-layer structure including a silicon oxide sublayer and a silicon nitride sublayer).

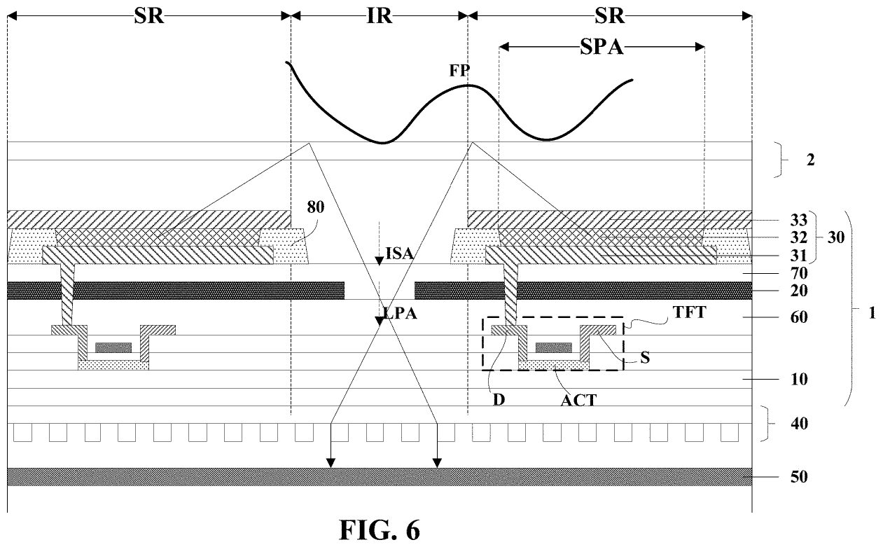

FIG. 6 is a schematic diagram illustrating the structure of an integrated photo-sensing detection display apparatus in some embodiments according to the present disclosure. Referring to FIG. 6, the light shielding layer 20 in some embodiments is made of an insulating material. Optionally, the first electrode 31 is electrically connected to the drain electrode D of a respective one of the plurality of thin film transistors TFT through a via extending through at least the light shielding layer 20. A light shielding layer 20 made of the insulating material obviates the parasitic capacitance issue.

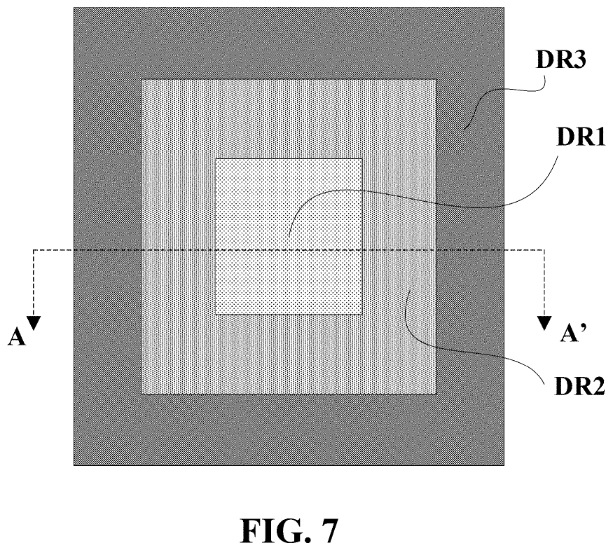

FIG. 7 is a schematic diagram illustrating the structure of a diffraction grating layer in some embodiments according to the present disclosure. Referring to FIG. 7, in some embodiments, the diffraction grating layer 40 includes a plurality of diffraction regions, for example, a first diffraction region DR1, a second diffraction region DR2, and a third diffraction region DR3, as shown in FIG. 7. Different diffraction regions of the diffraction grating layer 40 are configured to diffract an incident light at different exiting angles toward the photosensor.

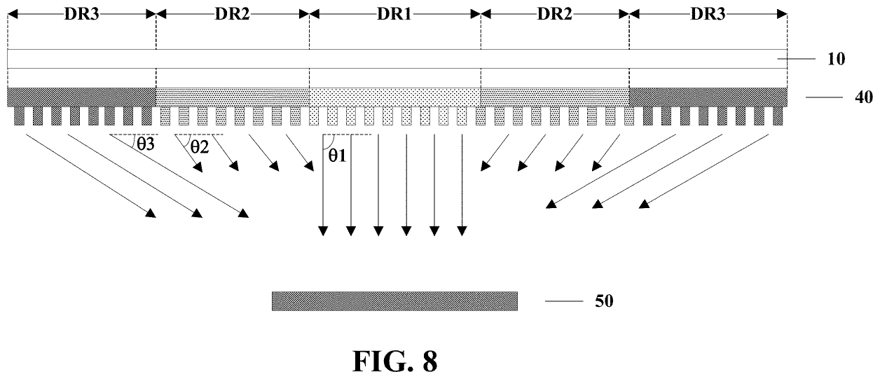

FIG. 8 illustrates a method of collimating light from different diffraction regions of a diffraction grating layer to a photosensor in some embodiments according to the present disclosure. Referring to FIG. 8, the first diffraction region DR1 is configured to collimate the signal-enriched light beam transmitted to the first diffraction region DR1 to exit the first diffraction region DR1 at a first exit angle θ1, thereby forming a first collimated light beam toward the photosensor 50. The second diffraction region DR2 is configured to collimate the signal-enriched light beam transmitted to the second diffraction region DR2 to exit the second diffraction region DR2 at a second exit angle θ2, thereby forming a second collimated light beam toward the photosensor 50. The third diffraction region DR3 is configured to collimate the signal-enriched light beam transmitted to the third diffraction region DR3 to exit the third diffraction region DR3 at a third exit angle θ3, thereby forming a third collimated light beam toward the photosensor 50. The first exit angle θ1, the second exit angle θ2, and the third exit angle θ3 are different from each other.

Based on the Equation (1) discussed above, various methods may be used to adjust the exit angles of different diffraction regions of the diffraction grating layer 40. In one example, the pitches of different diffraction regions may be adjusted to different values to achieve different exit angles. For example, in some embodiments, the first diffraction region DR1 has a first grating pitch, the second diffraction region DR2 has a second grating pitch, and the third diffraction region DR3 has a third grating pitch. The first grating pitch, the second grating pitch, and the third grating pitch are different from each other. In another example, the refractive index of the different diffraction regions may be adjusted to different values to achieve different exit angles. For example, in some embodiments, the first diffraction region DR1 has a first refractive index, the second diffraction region DR2 has a second refractive index, and the third diffraction region DR3 has a third refractive index. The first refractive index, the second refractive index, and the third refractive index are different from each other.

Optionally, the first diffraction region DR1 has a first inter-barrier distance between lateral walls of two directly adjacent barriers of the plurality of barriers in the first diffraction region DR1, the second diffraction region DR2 has a second inter-barrier distance between lateral walls of two directly adjacent barriers of the plurality of barriers in the second diffraction region DR2, and the third diffraction region DR3 has a third inter-barrier distance between lateral walls of two directly adjacent barriers of the plurality of barriers in the third diffraction region DR3.

Referring to FIG. 7 and FIG. 8, in some embodiments, the second diffraction region DR2 surrounds the first diffraction region DR1, and the third diffraction region DR3 surrounds the second diffraction region DR2. The first exit angle θ1 is greater than the second exit angle θ2, and the second exit angle θ2 is greater than the third exit angle θ3. Optionally, the first grating pitch is greater than the second grating pitch, which in turn is greater than the third grating pitch. Optionally, the first inter-barrier distance is greater than the second inter-barrier distance, which in turn is greater than the third inter-barrier distance.

Referring to FIG. 7 and FIG. 8, in some embodiments, an orthographic projection of the second diffraction region DR2 on the base substrate 10 is on a side of an orthographic projection of the first diffraction region DR1 on the base substrate 10 away from an orthographic projection of the photosensor 50 on the base substrate 10; and an orthographic projection of the third diffraction region DR3 on the base substrate 10 is on a side of an orthographic projection of the second diffraction region DR2 on the base substrate 10 away from an orthographic projection of the photosensor 50 on the base substrate 10.

In another aspect, the present disclosure provides an integrated photo-sensing detection display substrate having a subpixel region and an inter-subpixel region. In some embodiments, the integrated photo-sensing detection display substrate includes a base substrate; a plurality of light emitting elements on the base substrate and configured to emit light, a portion of the light being totally reflected by a surface thereby forming totally reflected light; a light shielding layer between the plurality of light emitting elements and the base substrate and configured to block at least a portion of diffusedly reflected light from passing through, the light shielding layer having a light path aperture in the inter-subpixel region allowing at least a portion of the totally reflected light to pass through thereby forming a signal-enriched light beam; a diffraction grating layer on a side of the base substrate away from the light path aperture and configured to at least partially collimate the signal-enriched light beam thereby forming a collimated light beam; and a photosensor on a side of the diffraction grating layer away from the base substrate and configured to detect the collimated light beam, thereby detecting fingerprint information.

In some embodiments, the light shielding layer has an area greater than an area of the subpixel region; and an orthographic projection of the light shielding layer on the base substrate covers an orthographic projection of the subpixel region on the base substrate. Optionally, the photosensor has an area smaller than an area of the integrated photo-sensing detection display substrate; and the diffraction grating layer is configured to form collimated light beams transmitting toward the photosensor respectively at different exit angles depending on a light exiting position on the diffraction grating layer relative to the photosensor. Optionally, the diffraction grating layer comprises a first diffraction region and a second diffraction region; the first diffraction region is configured to collimate a first signal-enriched light beam transmitted to the first diffraction region to exit the first diffraction region at a first exit angle, thereby forming a first collimated light beam toward the photosensor; and the second diffraction region is configured to collimate a second signal-enriched light beam transmitted to the second diffraction region to exit the second diffraction region at a second exit angle, thereby forming a second collimated light beam toward the photosensor. Optionally, the first diffraction region has a first grating pitch; the second diffraction region has a second grating pitch; and the first grating pitch and the second grating pitch are different from each other. Optionally, the second diffraction region surrounds the first diffraction region; and the first grating pitch is greater than the second grating pitch. Optionally, an orthographic projection of the second diffraction region on the base substrate is on a side of an orthographic projection of the first diffraction region on the base substrate away from an orthographic projection of the photosensor on the base substrate.

In some embodiments, the integrated photo-sensing detection display substrate further includes a plurality of thin film transistors configured to drive light emission of the plurality of light emitting elements. A respective one of the plurality of thin film transistors comprises a drain electrode. The light shield layer comprises a plurality of light shielding blocks spaced apart from each other. Optionally, a respective one of the plurality of light shielding blocks is electrically connected to the drain electrode of a respective one of the plurality of thin film transistors. Optionally, the integrated photo-sensing detection display substrate further includes a first insulating layer between the drain electrode and the light shield layer. Optionally, a respective one of the plurality of light emitting elements comprises a first electrode electrically connected to the light shielding layer. Optionally, the integrated photo-sensing detection display substrate further includes a second insulating layer between the first electrode and the light shield layer. Optionally, the second insulating layer extends into the light path aperture. Optionally, the first electrode is made of a substantially transparent conductive material.

In some embodiments, the integrated photo-sensing detection display substrate further includes a pixel definition layer defining a plurality of subpixel apertures. Optionally, the pixel definition layer has an inter-subpixel aperture in the inter-subpixel region allowing at least a portion of the totally reflected light to pass through sequentially the inter-subpixel aperture and the light path aperture. Optionally, the inter-subpixel aperture is larger than the light path aperture; and an orthographic projection of the light shielding layer on the base substrate covers an orthographic projection of the pixel definition layer on the base substrate.

In some embodiments, the diffraction grating layer is a nano-diffraction grating layer.

Optionally, an orthographic projection of the light shield layer on the base substrate is substantially non-overlapping with an orthographic projection of a plurality of data lines and a plurality of gate lines on the base substrate.

In another aspect, the present disclosure provides an integrated photo-sensing detection display panel including the integrated photo-sensing detection display substrate described herein or fabricated by a method described herein, and a counter substrate facing the integrated photo-sensing detection display substrate. As described above, the plurality of light emitting elements are configured to emit light toward the counter substrate, a portion of the light being totally reflected by a surface of the counter substrate facing away the integrated photo-sensing detection display substrate thereby forming the totally reflected light. The photosensor is configured to detect fingerprint information generated from a touch at any portion of the counter substrate.

In another aspect, the present disclosure provides a method of fabricating an integrated photo-sensing detection display apparatus having a subpixel region and an inter-subpixel region. In some embodiments, the method includes forming a counter substrate; and forming an array substrate facing the counter substrate. Optionally, the step of forming the array substrate includes forming a plurality of light emitting elements on a base substrate, and forming a light shielding layer between the plurality of light emitting elements and the base substrate. Optionally, the plurality of light emitting elements are formed to emit light toward the counter substrate, a portion of the light being totally reflected by a surface of the counter substrate facing away the array substrate thereby forming totally reflected light. Optionally, the light shielding layer is formed to block at least a portion of diffusedly reflected light from passing through, the light shielding layer formed to have a light path aperture in the inter subpixel region allowing at least a portion of the totally reflected light to pass through thereby forming a signal-enriched light beam. In some embodiments, the method further includes forming a diffraction grating layer on a side of the base substrate away from the light path aperture, and forming a photosensor on a side of the diffraction grating layer away from the base substrate. Optionally, the diffraction grating layer is formed to at least partially collimate the signal-enriched light beam thereby forming a collimated light beam. Optionally, the photosensor is formed to detect the collimated light beam, thereby detecting fingerprint information.

Optionally, the light shielding layer is formed to have an area greater than an area of the subpixel region, and an orthographic projection of the light shielding layer on the base substrate covers an orthographic projection of the subpixel region on the base substrate.

Optionally, the photosensor is formed to have an area smaller than a touch area or display area of the integrated photo-sensing detection display apparatus, and the diffraction grating layer is formed to diffract the collimated light beam transmitting toward the photosensor at different exit angles depending on a light exiting position on the diffraction grating layer relative to the photosensor. By having this design, the photosensor can detect fingerprint information generated from a touch at any portion of the counter substrate. e.g., any portion of the touch area or display area, which has an area larger than an area of the photosensor.

In some embodiments, the diffraction grating layer is formed to include a plurality of diffraction regions. In one example, the diffraction grating layer is formed to include a first diffraction region and a second diffraction region. Optionally, the method includes forming the first diffraction region for collimating the signal-enriched light beam transmitted to the first diffraction region to exit the first diffraction region at a first exit angle, thereby forming a first collimated light beam toward the photosensor; and forming the second diffraction region for collimating the signal-enriched light beam transmitted to the second diffraction region to exit the second diffraction region at a second exit angle, thereby forming a second collimated light beam toward the photosensor. Optionally, the first diffraction region is formed to have a first grating pitch, the second diffraction region is formed to have a second grating pitch. Optionally, the first grating pitch and the second grating pitch are different from each other. Optionally, the second diffraction region is formed surrounding the first diffraction region, and the first grating pitch is greater than the second grating pitch. Optionally, the first diffraction region and the second diffraction region are formed so that an orthographic projection of the second diffraction region on the base substrate is on a side of an orthographic projection of the first diffraction region on the base substrate away from an orthographic projection of the photosensor on the base substrate.

In some embodiments, the step of forming the light shielding layer includes forming a plurality of light shielding blocks spaced apart from each other. Optionally, a respective one of the plurality of light shielding blocks is formed to be electrically connected to a drain electrode of a respective one of the plurality of thin film transistors for driving light emission of the plurality of light emitting elements. Optionally, the method further includes forming a first insulating layer between the drain electrode and the light shield layer. Optionally, a respective one of the plurality of light shielding blocks is formed to be electrically connected to a first electrode of a respective one of the plurality of light emitting elements. Optionally, the method further includes forming a second insulating layer between the first electrode and the light shield layer. Optionally, the second insulating layer is formed to extend into the light path aperture. Optionally, the first electrode is made of a substantially transparent conductive material.

In some embodiments, the method further includes forming a pixel definition layer defining a plurality of subpixel apertures. Optionally, the pixel definition layer is formed to have an inter-subpixel aperture in the inter-subpixel region allowing at least a portion of the totally reflected light to pass through sequentially the inter-subpixel aperture and the light path aperture. Optionally, the inter-subpixel aperture is larger than the light path aperture, and an orthographic projection of the light shielding layer on the base substrate covers an orthographic projection of the pixel definition layer on the base substrate.

In another aspect, the present disclosure provides a method of fabricating an integrated photo-sensing detection display substrate having a subpixel region and an inter-subpixel region. In some embodiments, the method includes forming a plurality of light emitting elements on a base substrate, the plurality of light emitting elements formed to emit light, a portion of the light being totally reflected by a surface thereby forming totally reflected light; forming a light shielding layer between the plurality of light emitting elements and the base substrate, the light shielding layer formed to block at least a portion of diffusedly reflected light from passing through, the light shielding layer formed to have a light path aperture in the inter-subpixel region allowing at least a portion of the totally reflected light to pass through thereby forming a signal-enriched light beam; forming a diffraction grating layer on a side of the base substrate away from the light path aperture, the diffraction grating layer formed to at least partially collimate the signal-enriched light beam thereby forming a collimated light beam; and forming a photosensor on a side of the diffraction grating layer away from the base substrate, the photosensor formed to detect the collimated light beam, thereby detecting fingerprint information.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such waits should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. An integrated photo-sensing detection display substrate having a subpixel region and an inter-subpixel region, comprising:
a base substrate;
a plurality of light emitting elements on the base substrate and configured to emit light, a portion of the light being totally reflected by a surface thereby forming totally reflected light;
a light shielding layer between the plurality of light emitting elements and the base substrate and configured to block at least a portion of diffusedly reflected light from passing through, the light shielding layer having a light path aperture in the inter-subpixel region allowing at least a portion of the totally reflected light to pass through thereby forming a signal-enriched light beam;
a diffraction grating layer on a side of the base substrate away from the light path aperture and configured to at least partially collimate the signal-enriched light beam thereby forming a collimated light beam; and
a photosensor on a side of the diffraction grating layer away from the base substrate and configured to detect the collimated light beam, thereby detecting fingerprint information.

2. The integrated photo-sensing detection display substrate of claim 1, wherein the light shielding layer has an area greater than an area of the subpixel region; and
an orthographic projection of the light shielding layer on the base substrate covers an orthographic projection of the subpixel region on the base substrate.

3. The integrated photo-sensing detection display substrate of claim 1, wherein the photosensor has an area smaller than an area of the integrated photo-sensing detection display substrate; and
the diffraction grating layer is configured to form collimated light beams transmitting toward the photosensor respectively at different exit angles depending on a light exiting position on the diffraction grating layer relative to the photosensor.

4. The integrated photo-sensing detection display substrate of claim 3, wherein the diffraction grating layer comprises a first diffraction region and a second diffraction region;
the first diffraction region is configured to collimate a first signal-enriched light beam transmitted to the first diffraction region to exit the first diffraction region at a first exit angle, thereby forming a first collimated light beam toward the photosensor; and
the second diffraction region is configured to collimate a second signal-enriched light beam transmitted to the second diffraction region to exit the second diffraction region at a second exit angle, thereby forming a second collimated light beam toward the photosensor.

5. The integrated photo-sensing detection display substrate of claim 4, wherein the first diffraction region has a first grating pitch;
the second diffraction region has a second grating pitch; and
the first grating pitch and the second grating pitch are different from each other.

6. The integrated photo-sensing detection display substrate of claim 5, wherein the second diffraction region surrounds the first diffraction region; and
the first grating pitch is greater than the second grating pitch.

7. The integrated photo-sensing detection display substrate of claim 6, wherein an orthographic projection of the second diffraction region on the base substrate is on a side of an orthographic projection of the first diffraction region on the base substrate away from an orthographic projection of the photosensor on the base substrate.

8. The integrated photo-sensing detection display substrate of claim 1, further comprising a plurality of thin film transistors configured to drive light emission of the plurality of light emitting elements;
a respective one of the plurality of thin film transistors comprises a drain electrode;
the light shield layer comprises a plurality of light shielding blocks spaced apart from each other; and
a respective one of the plurality of light shielding blocks is electrically connected to the drain electrode of a respective one of the plurality of thin film transistors.

9. The integrated photo-sensing detection display substrate of claim 8, further comprising a first insulating layer between the drain electrode and the light shield layer.

10. The integrated photo-sensing detection display substrate of claim 8, wherein a respective one of the plurality of light emitting elements comprises a first electrode electrically connected to the light shielding layer.

11. The integrated photo-sensing detection display substrate of claim 10, further comprising a second insulating layer between the first electrode and the light shield layer.

12. The integrated photo-sensing detection display substrate of claim 11, wherein the second insulating layer extends into the light path aperture.

13. The integrated photo-sensing detection display substrate of claim 10, wherein the first electrode is made of a substantially transparent conductive material.

14. The integrated photo-sensing detection display substrate of claim 1, further comprising a pixel definition layer defining a plurality of subpixel apertures; and
the pixel definition layer has an inter-subpixel aperture in the inter-subpixel region allowing at least a portion of the totally reflected light to pass through sequentially the inter-subpixel aperture and the light path aperture.

15. The integrated photo-sensing detection display substrate of claim 14, wherein the inter-subpixel aperture is larger than the light path aperture; and
an orthographic projection of the light shielding layer on the base substrate covers an orthographic projection of the pixel definition layer on the base substrate.

16. The integrated photo-sensing detection display substrate of claim 1, wherein the diffraction grating layer is a nano-diffraction grating layer.

17. The integrated photo-sensing detection display substrate of claim 1, wherein an orthographic projection of the light shield layer on the base substrate is substantially non-overlapping with an orthographic projection of a plurality of data lines and a plurality of gate lines on the base substrate.

18. An integrated photo-sensing detection display panel, comprising:
the integrated photo-sensing detection display substrate of claim 1; and
a counter substrate facing the integrated photo-sensing detection display substrate;
wherein the plurality of light emitting elements are configured to emit light toward the counter substrate, a portion of the light being totally reflected by a surface of the counter substrate facing away the integrated photo-sensing detection display substrate thereby forming the totally reflected light; and
the photosensor is configured to detect fingerprint information generated from a touch at any portion of the counter substrate.

19. An integrated photo-sensing detection display apparatus, comprising the integrated photo-sensing detection display panel of claim 18, and one or more integrated circuits connected to the integrated photo-sensing detection display panel.

20. A method of fabricating an integrated photo-sensing detection display substrate having a subpixel region and an inter-subpixel region, comprising:
forming a plurality of light emitting elements on a base substrate, the plurality of light emitting elements formed to emit light, a portion of the light being totally reflected by a surface thereby forming totally reflected light;
forming a light shielding layer between the plurality of light emitting elements and the base substrate, the light shielding layer formed to block at least a portion of diffusedly reflected light from passing through, the light shielding layer formed to have a light path aperture in the inter-subpixel region allowing at least a portion of the totally reflected light to pass through thereby forming a signal-enriched light beam;
forming a diffraction grating layer on a side of the base substrate away from the light path aperture, the diffraction grating layer formed to at least partially collimate the signal-enriched light beam thereby forming a collimated light beam; and
forming a photosensor on a side of the diffraction grating layer away from the base substrate, the photosensor formed to detect the collimated light beam, thereby detecting fingerprint information.
